(19) United States
(12) Patent Application Publication
(10) Pub. No.: US 2015/0178524 A1
(43) Pub. Date: Jun. 25, 2015

(54) SYSTEM AND METHOD FOR WIRING CIRCUIT VERIFICATION OF VEHICLE

(71) Applicant: Hyundai Motor Company, Seoul (KR)

(72) Inventor: Geon O KWON, Bucheon-si (KR)

(21) Appl. No.: 14/325,954

(22) Filed: Jul. 8, 2014

(30) Foreign Application Priority Data
Dec. 23, 2013 (KR) 10-2013-0161721

(51) Int. Cl. G06K 7/10; G01R 31/28

(52) U.S. Cl. CPC G06K 7/10128; G01R 31/28

(57) ABSTRACT

A system for wiring circuit verification of a vehicle includes a wiring, an RFID receiver, a main server, and a work instruction monitor. An RFID product label is attached with the wiring. The RFID receiver is configured to recognize wiring product information by communicating with the RFID product label in the vehicle. The main server is configured to receive the wiring product information from the RFID receiver to extract a circuit component of a wiring part number applied to the vehicle and refer to design data to verify whether wiring circuits are matched with each other. The work instruction monitor is configured to display a result of the verification to determine whether a wiring circuit matchability problem is present.

### CROSS-REFERENCE TO RELATED APPLICATION

This application claims priority to and the benefit of Korean Patent Application No. 10-2013-0161721 filed in the Korean Intellectual Property Office on Dec. 23, 2013, the entire contents of which are incorporated herein by reference.

### TECHNICAL FIELD

The present inventive concept relates to a system and a method for wiring circuit verification of a vehicle, and more particularly, to a system and a method for wiring circuit verification of a vehicle using a smart radio frequency identification (RFID) at the time of manufacturing the vehicle.

### BACKGROUND

Generally, many electrical parts are equipped in a vehicle and as the number and kind of electrical parts and the number of wirings equipped in one complete vehicle are increased, individual wiring circuit verification of a single item becomes complicated and a number of attempts to manage the verified result are required.

FIG. 1 illustrates a number of wiring options for each portion in a vehicle (e.g., an anti-lock braking system (ABS), an advanced traffic management (ATM) system, an engine management system (EMS)) according to the related art.

Referring to FIG. 1, for example, about 15 wiring options are applied to each portion of a vehicle, and the number of wiring specifications of wiring part number (P/NO) is determined by the number of options applied to the vehicle.

In this case, the wiring specifications mean a unique identification code for differentiating numerous wiring products which are generated by various combinations of options configuring one vehicle.

The wiring has the largest number of specifications among parts configuring one vehicle and the total number of specifications reaches 3,000 to 5,000 on average.

Therefore, the number of combinations of options configuring a vehicle with about 5,000 specifications is several millions, which makes it impossible to actually perform simulation on verification of the wiring circuit prior to manufacturing a vehicle.

Further, a method of determining a wiring part number (P/NO) applied to the vehicle in the state in which a vehicle assembling is completed is not yet present.

Therefore, problems, such as circuit omission and circuit PIN unmatching, may occur in a vehicle which is actually mass produced. As a result, vehicle quality may be lowered and brand image may be declined at home or abroad due to a rework campaign.

The above information disclosed in this Background section is only for enhancement of understanding of the background of the inventive concept and therefore it may contain information that does not constitute the prior art that is already known.

### SUMMARY

The present inventive concept has been made in an effort to provide a system and method for wiring circuit verification of a vehicle capable of preventing a malfunction of electrical parts of a vehicle due to a circuit omission and an unmatching occurrence, by equipping RFID chips in wirings which are used in mass production of a vehicle and verifying matchability of internal circuits of the vehicle in real time using an RFID receiver mounted on a line during the assembling and moving of a vehicle.

An aspect of the present inventive concept relates to a system for wiring circuit verification of a vehicle, including a wiring, an RFID receiver, a main server and a work instruction monitor. An RFID product label is attached to the wiring. The RFID receiver is configured to recognize wiring product information by communicating with the RFID product label in the vehicle. The main server is configured to receive the wiring product information from the RFID receiver to extract a circuit component of a wiring part number applied to the vehicle and refer to design data to verify whether wiring circuits are matched with each other. The work instruction monitor is configured to display a result of the verification to determine whether a wiring circuit matchability problem is present.

The attached RFID product label may embed an RFID chip storing the wiring product information and enclose a part of the wirings in a wiring production stage.

The wiring product information may include at least one of the wiring part number, an application portion within the vehicle, a specification, and supplier information.

The RFID receiver may be a plurality of RFID receivers disposed at left and right sides of an assembly moving line such that when the vehicle enters between two of the plurality of RFID receivers, the plurality of RFID receivers transmit the wiring product information within the vehicle which is recognized by each of the RFID receivers to the main server in real time.

The RFID receiver may be configured to additionally recognize identification information of the vehicle entering within a recognizable distance and transmit the recognized identification information to the main server along with the wiring product information.

The main server may be configured to accumulatively store a successful result of verifying the corresponding vehicle when it is determined that a result the verification is normal and to display the successful result through the work instruction monitor.

The main server may be configured to analyze causes of unmatching when it is determined based on a result of the verification that the unmatching occurs. The main server may be configured to accumulatively store a portion at which the unmatching occurs and the wiring product information along with an unsuccessful result and display and warn the unsuccessful result through a work instruction monitor.

The design data may include wiring design data depending on a vehicle model and different wiring design data for each option for the same vehicle model.

The main server may be configured to analyze accumulatively stored verification result data to be used as reference data for job evaluation of a field worker or a design worker or understand a defective rate of a supplier of wiring to be used as corrective data.

Another aspect of the present inventive concept encompasses a method for wiring circuit verification of an assembled vehicle in mass production of the vehicle, including step a) applying and installing a wiring with which an RFID product label is attached at the time of assembling the vehicle. In step b), wiring product information recognized by communicating with the RFID product label installed in the vehicle is collected from a plurality of RFID receivers installed at left and right sides of an assembling moving line. In step c), the received wiring product information is analyzed to acquire a corresponding wiring part number and extracting circuit components for each acquired part number applied to the vehicle to verify whether wiring circuits are matched with each other. In step d), when it is determined based on a result of the verification that unmatching occurs, an unsuccessful result is displayed and warned through a work instruction monitor.

In step b), identification information of the vehicle including information on a vehicle model and options to be applied may be further collected from the RFID receiver.

In step c), it may be verified whether the wiring circuits are matched with each other by referring to wiring design data depending on the vehicle model and the option to be applied.

Step d) may include accumulatively storing a portion at which unmatching occurs and the wiring product information along with an unsuccessful result.

Step d) may include storing a successful result of the corresponding vehicle when it is determined based on a result of the verification that the matching is normal and displaying the successful result through the work instruction monitor.

According to aspects of the present inventive concept, it is possible to prevent the malfunction of electrical parts of the vehicle due to the circuit omission and the unmatching occurrence, by equipping the RFID chips in the wirings which is applied in mass production of the vehicle and verifying the matchability of internal circuits of the vehicle in real time using the RFID receiver mounted on the line during the assembling and moving of the vehicle.

Further, it is possible to prevent the product from being damaged due to the wiring rework by correcting the mistake of the suppliers of the wiring based on the objective verification result without relying on the verification results by the traditional suppliers of the wiring.

### BRIEF DESCRIPTION OF THE DRAWINGS

FIG. 1 is a diagram illustrating a number of wiring options for each portion in a vehicle according to the related art.

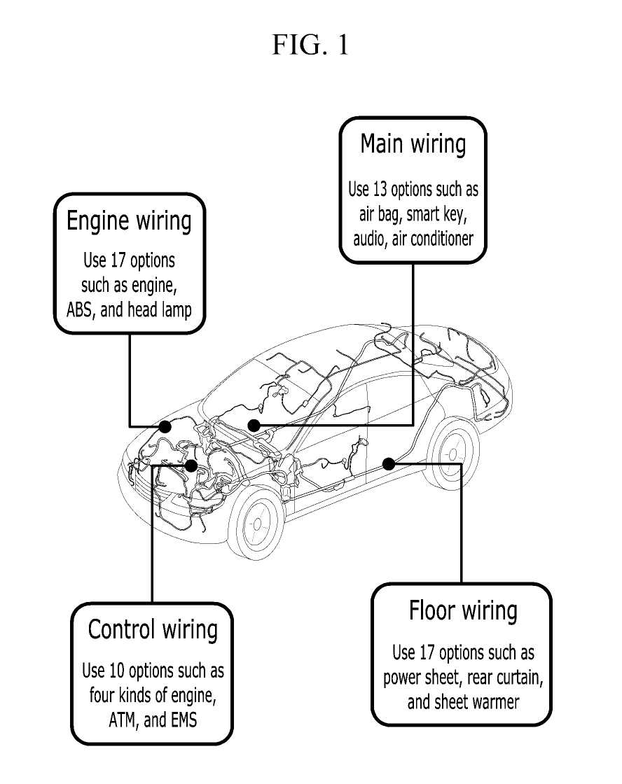

FIG. 2 is a diagram illustrating a general wiring circuit unmatching type occurrence during mass production of a vehicle.

FIG. 3 is a diagram schematically illustrating a configuration of a system for wiring circuit verification of a vehicle according to an exemplary embodiment of the present inventive concept.

FIG. 4 is an exploded perspective view of an RFID product label according to an exemplary embodiment of the present inventive concept.

FIG. 5 is a diagram illustrating a state in which an RFID product label is attached to a wiring applied in a vehicle according to the exemplary embodiment of the present inventive concept.

FIG. 6 is a flow chart schematically illustrating a method for wiring circuit verification of a vehicle according to an exemplary embodiment of the present inventive concept.

### DETAILED DESCRIPTION

In the following detailed description, only certain exemplary embodiments of the present inventive concept have been shown and described, simply by way of illustration. As those skilled in the art would realize, the described embodiments may be modified in various different ways, all without departing from the spirit or scope of the present inventive concept. Accordingly, the drawings and description are to be regarded as illustrative in nature and not restrictive. Like reference numerals designate like elements throughout the specification.

Throughout this specification, unless explicitly described to the contrary, the word “comprise” and variations such as “comprises” or “comprising”, will be understood to imply the inclusion of stated elements but not the exclusion of any other elements. In addition, the terms “-er”, “-or” and “module” described in the specification mean units for processing at least one function and operation and can be implemented by hardware components (microprocessors, microcontroller and the like) or software components and combinations thereof.

Hereinafter, a system and a method for wiring circuit verification of a vehicle according to an exemplary embodiment of the present inventive concept will be described in detail with the accompanying drawings.

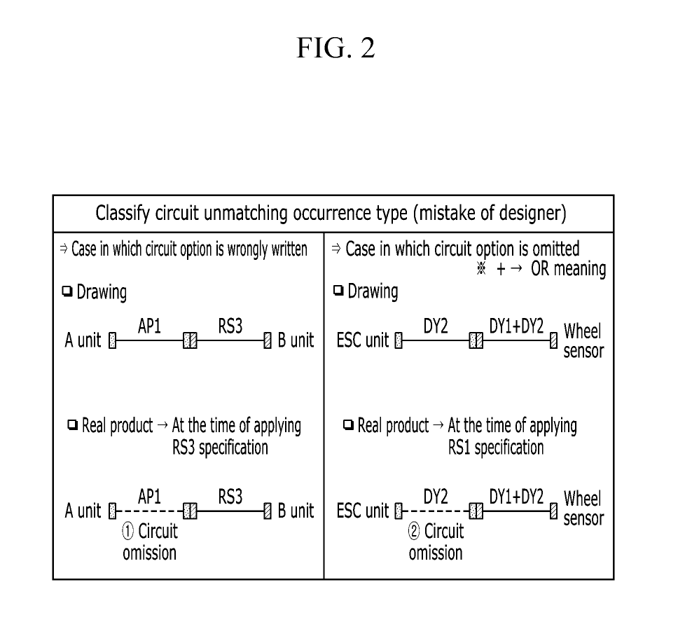

Prior to describing the exemplary embodiment of the present inventive concept, a circuit unmatching type generally occurring will be described with reference to FIG. 2

FIG. 2 is a diagram illustrating a general wiring circuit unmatching type that occurs during mass production of a vehicle.

Referring to FIG. 2, the circuit unmatching may occur due to a mistake of a designer and an example thereof may mainly include a case in which an option setting of a wiring circuit is incorrectly designated.

For an exemplary case in which a circuit option is incorrectly written, when a system called RS3 specification is applied between A unit and B unit (see FIG. 2) but is incorrectly written as AP1, a real product may be manufactured while the corresponding wiring is omitted.

Further, for an exemplary case in which a circuit option is omitted, when a DY1 or DY2 system as RS1 specification is applied between an electronic stability control (ESC) unit and a wheel sensor (see FIG. 2), the relevant wiring needs to be equipped in a product, but the real product may be manufactured while the relevant wiring is omitted (e.g., unavailable) when the DY1 system is equipped in the vehicle.

Therefore, in order to solve the above problem, according to an exemplary embodiment of the present inventive concept, a system is provided for wiring circuit verification capable of verifying circuit matchability in real time in a design final line assembling process of a vehicle by embedding smart radio frequency identification (RFID) chips in each wiring product label.

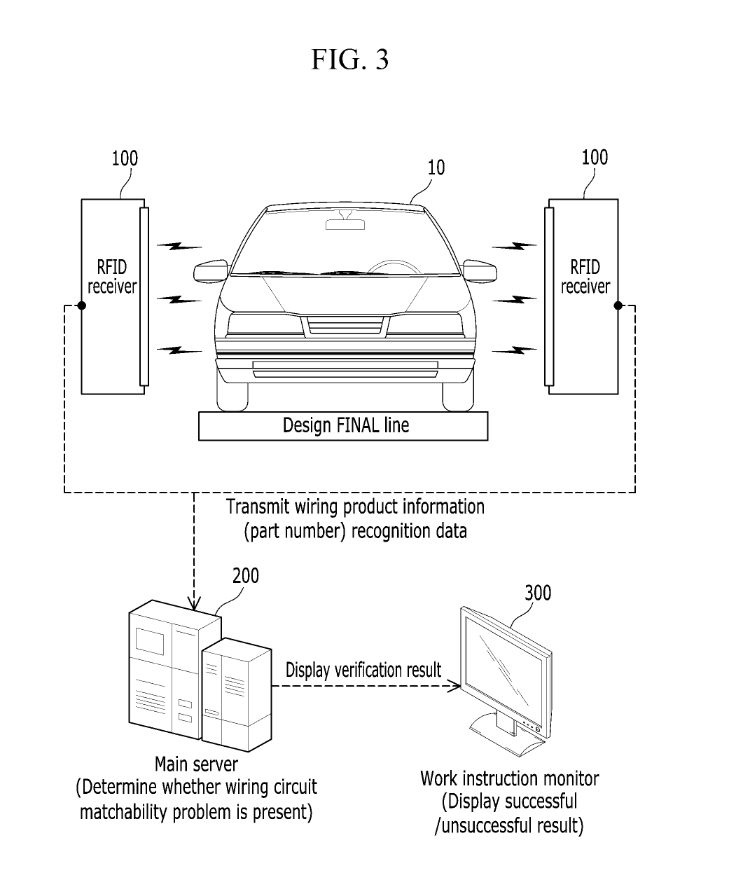

Meanwhile, FIG. 3 is a diagram schematically illustrating a configuration of a system for wiring circuit verification of a vehicle according to an exemplary embodiment of the present inventive concept.

Referring to FIG. 3, a system for wiring circuit verification according to an exemplary embodiment of the present inventive concept may include a vehicle 10, an RFID receiver 100, a main server 200, and a work instruction monitor 300.

A wiring to which an RFID product label is attached may be applied to the vehicle 10.

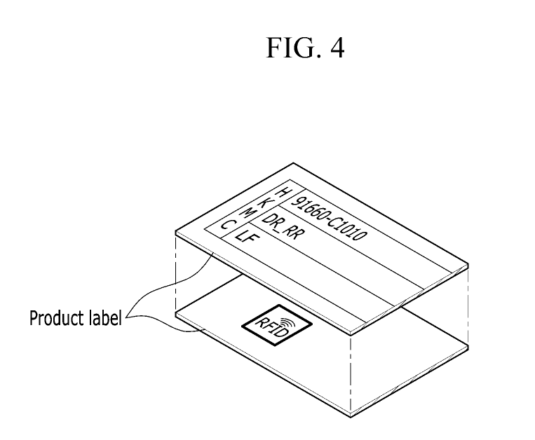

FIG. 4 is an exploded perspective view of an RFID product label according to an exemplary embodiment of the present inventive concept.

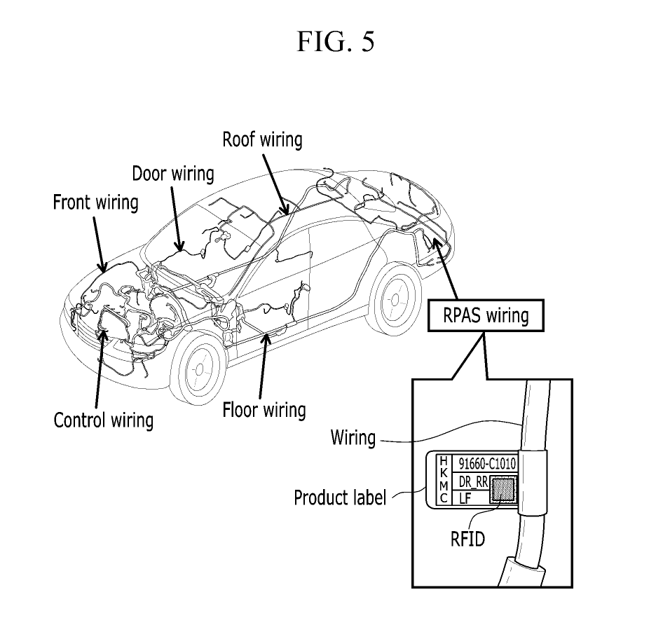

FIG. 5 is a diagram illustrating a state in which an RFID product label is attached to a wiring applied in a vehicle according to the exemplary embodiment of the present inventive concept.

Referring to FIGS. 4 and 5, an RFID product label may embed therein a smart RFID chip storing wiring product information at the time of producing the wiring and may be attached in a form of enclosing a part of the corresponding wiring.

In this case, the wiring product information stored in the RFID chip may include information on a part number (P/NO) of the wiring, an application portion, a specification, and supplier.

For example, the vehicle 10 may be applied with approximately 17 wirings per vehicle. As illustrated in FIG. 5, the wirings applied to each portion of the vehicle may have attached therewith RFID product labels to allow a noncontact individual recognition for a vehicle in a stage of assembling completion.

The RFID receiver 100 may communicate with the RFID product labels in the vehicle to recognize the wiring product information stored in the RFID chip.

The plurality of RFID receivers 100 may be installed at left and right sides of a design final line (see FIG. 3). When the vehicle enters between the two RFID receivers 100, the plurality of RFID receivers 100 may transmit the wiring product information within the vehicle which is recognized by each of the RFID receivers to the main server 200 in real time.

Further, the RFID receivers 100 may additionally recognize identification information of the entering vehicle and may transmit the recognized identification information to the main server 200.

When the main server 200 receives the wiring product information from the RFID receiver 100, it may be verified based on the design data of the vehicle whether the wiring circuits of the vehicle are matched with each other (or with the design data).

The main server 200 may analyze the received wiring product information to acquire the wiring part number (P/NO) applied to the corresponding vehicle and may extract a circuit component of the acquired part number and refer to design data, thereby verifying whether the wiring circuits are matched with each other (or with the design data).

Further, if it is determined, based on the verification result on whether the wiring circuits are matched with each other (or with the design data), that the matching is normal, the main server 200 may store a successful result of the corresponding vehicle and display a successful result through the work instruction monitor 300.

On the other hand, if it is determined, based on the verification result on whether the wiring circuits are matched with each other (or with the design data), that abnormality, such as unmatching, occurs, the main server 200 may analyze causes of the abnormality, store an unsuccessful result along with the analyzed causes, and display and warn the unsuccessful result and the causes of abnormality through the work instruction monitor 300.

Next, the main server 200 may analyze accumulatively stored verification result data to be used as a reference data for job evaluation of a field worker or a design worker and understand a defective rate of a supplier of wiring to correct defective rate of the supplier of wiring.

Meanwhile, the design data may include wiring design data depending on a vehicle model and different wiring design data may exist for each option even for the same vehicle model.

It is common to assemble the same vehicle model in a production line of a vehicle, but as convenient specifications of a vehicle are increased recently, options to be applied may be different even though a vehicle model assembled in one line is the same. Therefore different wiring design data (e.g., option design data) may also be applied to the same vehicle model.

Therefore, the main server 200 may further receive the identification information of the vehicle which is received from the RFID receiver 100 to verify wiring matchability based on the option design data of the corresponding vehicle.

The work instruction monitor 300 may display the verification result depending on whether the wiring matchability problem of the vehicle is present from the main server 200.

In this case, the work instruction monitors 300 may be installed in a work management center in which the main server 200 is located and the design final line, respectively, and may directly warn an appropriate corrective measure on the spot depending on a diagnosis result.

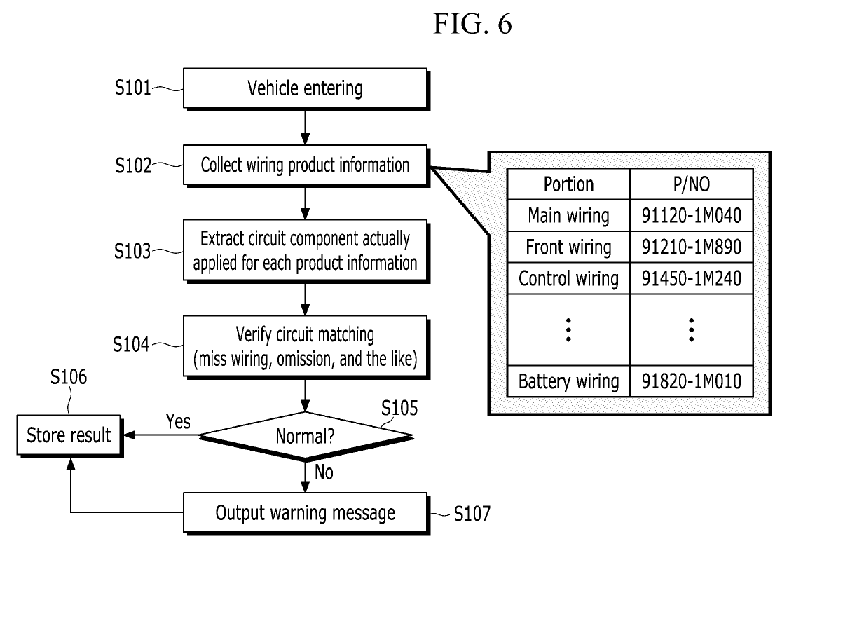

Meanwhile, a method for wiring circuit verification of a vehicle based on the configuration of the system for wiring circuit verification according to an exemplary embodiment of the present inventive concept will be described with reference to FIG. 6.

FIG. 6 is a flow chart schematically illustrating a method for wiring circuit verification of a vehicle according to an exemplary embodiment of the present inventive concept.

Referring to FIG. 6, when the vehicle 10 enters between the RFID receivers 100 which are installed at both sides along an assembly moving line (S101), the main server 200 according to an exemplary embodiment of the present inventive concept may collect the wiring product information recognized by communication with the RFID equipped in the vehicle 10 from the RFID receivers 100 (S102). In this case, the main server 200 may receive the collected wiring product information from the RFID receivers 100 and analyze the received wiring product information to acquire the corresponding wiring part number (P/NO).

Further, the main server 200 may collect the identification information of the vehicle, which includes information on the vehicle model and the options to be applied, from the RFID receiver 100.

The main server 200 may extract the circuit components applied to the vehicle for each acquired part number (S103) and refer to the design data, thereby verifying whether the wiring circuits are matched with each other (or with the design data) (S104).

In this case, the main server 200 may refer to the wiring design data depending on the vehicle model and the options to be applied, thereby verifying whether the wiring circuits of the vehicle 10 are matched with each other (or with the design data).

If it is determined, based on the verification result on whether the wiring circuits are matched with each other (or with the design data), that the matching is normal (S105, YES), the main server 200 may store the successful result of the corresponding vehicle (S106).

On the other hand, if it is determined, based on the verification result on whether the wiring circuits are matched with each other (or with the design data), that abnormality such as unmatching occurs (S105, NO), the main server 200 may analyze the causes of the abnormality to output a display and warning message through the work instruction monitor (S107) and store the unsuccessful result (S106).

As described above, according to the exemplary embodiments of the present inventive concept, it is possible to prevent the malfunction of electrical parts of the vehicle due to the circuit omission and the unmatching occurrence, by equipping the RFID chips in the wirings which are applied in mass production of the vehicle and verifying the matchability of internal circuits of the vehicle in real time using the RFID receiver mounted on the line during the assembling and moving of the vehicle.

Further, it is possible to prevent the product from being damaged due to the wiring rework by correcting the mistake of the suppliers of the wiring based on the objective verification result without relying on the verification results of the traditional suppliers of the wiring.

The exemplary embodiments of the present inventive concept may be implemented not only by the apparatus and/or the method as described above but also may be implemented by a program, a recording medium recorded with the program, and the like for realizing the functions corresponding to the configuration of the exemplary embodiment of the present inventive concept and may be easily implemented by a person having ordinary skill in the art to which the present inventive concept pertains from the descriptions of the foregoing exemplary embodiment.

While this inventive concept has been described in connection with what is presently considered to be practical exemplary embodiments, it is to be understood that the inventive concept is not limited to the disclosed embodiments, but, on the contrary, is intended to cover various modifications and equivalent arrangements included within the spirit and scope of the appended claims.

1. A system for wiring circuit verification of a vehicle, comprising:
a wiring with which a radio frequency identification (RFID) product label is attached;
an RFID receiver configured to recognize wiring product information by communicating with the RFID product label in the vehicle;
a main server configured to receive the wiring product information from the RFID receiver to extract a circuit component of a wiring part number applied to the vehicle and refer to design data to verify whether wiring circuits are matched with each other; and
a work instruction monitor configured to display a result of the verification to determine whether a wiring circuit matchability problem is present.

2. The system of claim 1, wherein the attached RFID product label embeds an RFID chip storing the wiring product information and encloses a part of the wiring in a wiring production stage.

3. The system of claim 1, wherein the wiring product information includes at least one of the wiring part number, an application portion within the vehicle, a specification, and supplier information.

4. The system of claim 1, wherein the RFID receiver is a plurality of RFID receivers disposed at left and right sides of an assembly moving line such that when the vehicle enters between two of the plurality of RFID receivers, the plurality of RFID receivers are configured to transmit the wiring product information within the vehicle which is recognized by each of the RFID receivers to the main server in real time.

5. The system of claim 1, wherein the RFID receiver is configured to additionally recognize identification information of the vehicle entering within a predetermined distance and transmit the recognized identification information to the main server along with the wiring product information.

6. The system of claim 1, wherein the main server is configured to accumulatively store a successful result of verifying the corresponding vehicle when it is determined that a result of the verification is normal, and display the successful result through the work instruction monitor.

7. The system of claim 1, wherein:
when it is determined based on a result of the verification that unmatching occurs, the main server is configured to analyze causes of the unmatching, and
the main server is configured to accumulatively store a portion at which the unmatching occurs and the wiring product information along with an unsuccessful result and display and warn the unsuccessful result through a work instruction monitor.

8. The system of claim 1, wherein the design data include wiring design data depending on a vehicle model and different wiring design data for each option for the same vehicle model.

9. The system of claim 1, wherein the main server is configured to analyze accumulatively stored verification result data to be used as reference data for job evaluation of a field worker or a design worker or to understand a defective rate of a supplier of wiring to be used as corrective data.

10. A method for wiring circuit verification of an assembled vehicle during mass production of the vehicle, the method comprising steps of:
a) applying and installing a wiring with which an RFID product label is attached at the time of assembling the vehicle;
b) collecting wiring product information recognized by communicating with the RFID product label installed in the vehicle from a plurality of RFID receivers installed at left and right sides of an assembling moving line;
c) analyzing the received wiring product information to acquire a corresponding wiring part number and extracting circuit components for each acquired part number applied to the vehicle to verify whether wiring circuits are matched with each other; and
d) when it is determined based on a result of the verification that unmatching occurs, displaying and warning an unsuccessful result through a work instruction monitor.

11. The method of claim 10, wherein step b) includes collecting from the RFID receivers identification information of the vehicle including information on a vehicle model and options to be applied.

12. The method of claim 10 or 11, wherein step c) includes verifying whether the wiring circuits are matched with each other by referring to wiring design data depending on the vehicle model and the option to be applied.

13. The method of claim 10, wherein step d) includes accumulatively storing a portion at which the unmatching occurs and the wiring product information along with an unsuccessful result.

14. The method of claim 10, wherein step d) includes storing a successful result of the corresponding vehicle when it is determined based on a result of the verification that the matching is normal and displaying the successful result through the work instruction monitor.
